(19) United States
(12) Patent Application Publication
(10) Pub. No.: US 2026/0129767 A1
(43) Pub. Date: May 7, 2026

(54) Systems and Methods for Liquid Metal Printing

(71) Applicant: The Regents of the University of California, Oakland, CA (US)

(72) Inventors: Ximin He, Los Angeles, CA (US); Dong Wu, Torrance, CA (US)

(73) Assignee: The Regents of the University of California, Oakland, CA (US)

(21) Appl. No.: 19/368,937

(22) Filed: Oct. 24, 2025

Related U.S. Application Data
(60) Provisional application No. 63/717,762, filed on Nov. 7, 2024.

(51) Int. Cl. H05K 3/12

(52) U.S. Cl. CPC H05K 3/1275; H05K 3/1283; H05K 2203/0502

(57) ABSTRACT

A method for forming conductive and stretchable traces on a substrate is disclosed. A photocurable ink is prepared by dispersing surface-modified liquid-metal particles in a solvent together with monomers, crosslinkers, dispersant, and photoinitiator. The ink is deposited onto a substrate and selectively exposed to patterned light to initiate photopolymerization and crosslinking of the functionalized particle surfaces, forming a patterned liquid-metal-polymer composite anchored to the substrate. Subsequent mechanical activation ruptures oxide shells surrounding the particles and allows the liquid-metal cores to merge into a continuous conductive layer that conforms to the projected pattern. The process operates under ambient conditions with low energy input and short exposure time, providing high-resolution, durable, and deformable conductive features suitable for wearable electronics, biointegrated sensors, and soft-robotic devices.

### CROSS-REFERENCE TO RELATED APPLICATIONS

The current application claims the benefit of and priority under 35 U.S.C. § 119(e) to U.S. Provisional Patent Application No. 63/717,762 entitled “Liquid Metal Printing Technique via Optical Maskless Lithography” filed Nov. 7, 2024. The disclosure of U.S. Provisional Patent Application No. 63/717,762 is hereby incorporated by reference in its entirety for all purposes.

### FIELD OF THE INVENTION

This application generally refers to systems for liquid metal printing. More specifically, this application relates to liquid metal printing processes via optical maskless lithography (OML), flexible circuit design, devices using flexible circuit technologies and various aspects of their manufacture.

### BACKGROUND

Soft electronic circuits are fundamental components for a broad range of emerging technologies, including wearable electronics, biomedical devices, and soft robotics. These applications demand conductive materials that provide not only high electrical conductivity but also intrinsic flexibility, stretchability, and mechanical robustness under deformation. Traditional approaches to achieving stretchability often involve engineering rigid conductive materials into specialized geometries, such as serpentine structures. However, these structure-based designs typically offer limited stretchability and occupy significant device real estate. Alternatively, conductive composites, which incorporate fillers such as carbon materials or metallic nanoparticles into elastomer matrices, have been explored. While improving stretchability, these composites often sacrifice electrical conductivity due to limited conductive pathways and poor interfaces between the fillers and the matrix. Room-temperature liquid metals (LMs), such as eutectic gallium-indium (EGaIn), have emerged as highly promising candidates due to their unique combination of metallic conductivity and fluidic compliance. However, the effective manufacturing and high-resolution patterning of LMs remain significant challenges that hinder their widespread adoption.

Current state-of-the-art methods for liquid metal patterning suffer from several drawbacks. Conventional techniques often rely on pre-patterned structures. For example, stencil or screen printing requires the fabrication of physical masks. Similarly, injecting or vacuum-filling LM into microfluidic channels requires prefabricated molds. These mask- or mold-dependent approaches are time-consuming, costly, and ill-suited for rapid prototyping or customization. Direct additive manufacturing strategies have been utilized to print LMs. Direct writing and inkjet printing offer maskless patterning capabilities. However, these are inherently serial processes, which limits manufacturing throughput. Furthermore, these nozzle-based methods frequently suffer from clogging issues, difficulties in precise extrusion control, and limited printing resolution. Other approaches utilize Liquid Metal Particles (LMPs). These methods typically involve dispersing LMPs within a polymer matrix and subsequently sintering the desired traces using high-energy inputs, such as lasers, or localized pressure to form conductive paths. These methods often result in limited inter-particle connection, relatively low conductivity, and require multi-step, high-energy processes that may damage sensitive flexible polymeric substrates.

Optical Maskless Lithography (OML), such as Digital Light Processing (DLP)-based projection lithography, is a well-established high-resolution and high-throughput printing technique. DLP utilizes parallel processing (patterning an entire layer simultaneously) for rapid fabrication of polymers and certain metals. Despite its significant advantages in speed and precision, DLP has not been successfully utilized for printing conductive LM circuits, primarily due to the lack of suitable photo-crosslinkable LM inks and compatible processing methods.

Accordingly, there remains a significant unmet need for a fast, scalable, nozzle-free, and parallel direct printing method capable of fabricating high-resolution, highly conductive, and stretchable liquid metal patterns under ambient conditions with low energy input.

### SUMMARY OF THE INVENTION

The present disclosure provides systems and methods for rapid, high-resolution fabrication of conductive liquid metal patterns using optical maskless lithography (OML), such as Digital Light Processing (DLP)-based projection lithography. The techniques disclosed herein enable a fast, scalable, nozzle-free, and parallel printing process under ambient conditions.

In some embodiments, the disclosure is directed to a printable fluid composition (ink) formulated for OML. The ink comprises liquid metal particles (LMPs) with chemically modified surfaces, at least one monomer, at least one crosslinker, a dispersant, a photoinitiator, and a solvent. The surface modification of the LMPs (e.g., functionalization with ligands containing alkene or thiol groups) enables them to participate in the photopolymerization process upon exposure to patterned light.

In various embodiments, the liquid metal comprises a gallium-based alloy, such as eutectic gallium-indium (EGaIn). In some embodiments, the monomer (e.g., 2-hydroxyethyl acrylate) is selected to form a stretchable and adhesive polymeric layer or matrix upon polymerization.

In several embodiments, the disclosure is directed to a method of manufacturing a conductive device. The method includes depositing the photo-crosslinkable LMP ink onto a substrate and exposing the ink to a digitally generated light pattern (e.g., UV light). This exposure simultaneously initiates photopolymerization of the monomers and crosslinking of the modified LMPs, generating a patterned liquid metal-polymer structure anchored to the substrate in a single step.

In many embodiments, the method further comprises rinsing away non-crosslinked components and applying mechanical sintering (e.g., rubbing, compressing, or peeling) to the patterned structure. The mechanical sintering ruptures the oxide shells of the LMPs, allowing the liquid metal cores to coalesce and form continuous conductive pathways. The fabrication process is notably rapid, often requiring about 5 to 10 seconds of light exposure under ambient conditions.

In certain embodiments, the disclosure is directed to a device fabricated using the disclosed methods. The device comprises at least one patterned liquid metal trace confined and anchored to a substrate via an in-situ polymerized layer. The substrate can be rigid, flexible, or stretchable (e.g., PET or SIS).

In certain embodiments, the resulting structure exhibits a bilayer configuration, wherein a continuous liquid metal layer is situated atop an adhesive polymer layer (e.g., PHEA). This structure facilitates exceptional performance, including high electrical conductivity (e.g., approximately 3.0×10⁶ S/m), high resolution (e.g., approximately 20 μm), and extreme stretchability (e.g., up to 2500%) with excellent electromechanical stability under deformation.

Some embodiments are directed to a system for liquid metal printing, comprising: a substrate configured to hold an ink, wherein the ink comprises liquid metal particles, monomers, crosslinkers, photoinitiators, and a solvent, wherein the liquid metal particles are dispersed in the solvent, and the monomers, crosslinkers, and photoinitiators are dissolved in the solvent; wherein each of the liquid metal particles comprises an oxide shell and the oxide shell is modified with ligands; a light source configured to emit a light; a spatial light modulator configured to project the light with a pattern, wherein the light is projected to the ink on the substrate such that the ink is exposed to the light and the light initiates a photopolymerization process where the monomers are polymerized and crosslinked with the liquid metal particles to form a composite on the substrate; wherein the composite conforms to the pattern; and a sintering apparatus, wherein the sintering apparatus is configured to apply a mechanical activation to the composite; wherein the mechanical activation ruptures the oxide shell and coalesces the liquid metal particles to form a continuous conductive layer atop the polymerized and crosslinked monomers.

In some embodiments, the ink further comprises one or more dispersants configured to disperse the liquid metal particles and stabilize the ink.

In some embodiments, each of the liquid metal particles comprises a gallium-based alloy in a liquid form at a temperature range between 15 degrees Celsius and 25 degrees Celsius; wherein each of the liquid metal particles further comprises at least one of In, Sn, Bi, Sb, and Zn.

In some embodiments, each of the liquid metal particles comprises EGaIn.

In some embodiments, the oxide shell comprises a metal oxide comprising at least one cation derived from a metal selected from the group consisting of Ga, In, Sn, Bi, Sb, and Zn.

In some embodiments, each of the ligands is covalently or coordinatively bound to the oxide shell; wherein a terminal end of each of the ligands comprises an alkene group or a thiol group to enable crosslinking.

In some embodiments, each of the ligands comprises at least one functional group selected from the group consisting of a hydroxyl, a thiol, a phosphonic acid, a carboxylic acid, a silane, and an amine.

In some embodiments, each of the monomers comprises an acrylate for the photopolymerization process.

In some embodiments, the crosslinkers comprise at least one crosslinker selected from the group consisting of a diacrylate, a trifunctional acrylate, and a tetrafunctional acrylate.

In some embodiments, the one or more dispersants comprise at least one material selected from the group consisting of a polymeric dispersant, an anionic surfactant, a cationic surfactant, and a zwitterionic dispersant.

In some embodiments, the photoinitiators comprise at least one material selected from the group consisting of a Type-I α-cleavage initiator, a Type-II initiator, a photoredox catalyst, an acylgermane, a cationic, and a cationic hybrid system.

In some embodiments, the sintering apparatus is configured to sinter the composite mechanically, chemically, or electrically.

In some embodiments, the substrate is rigid or flexible.

In some embodiments, the light is UV light.

In some embodiments, the light is projected using digital light processing or optical maskless lithography.

In some embodiments, the light is projected from under the substrate; wherein the substrate is transparent to the light.

In some embodiments, the ink is exposed to the light less than or equal to 30 seconds.

Some embodiments include method, comprising: depositing an ink on a substrate, wherein the ink comprises liquid metal particles, monomers, crosslinkers, photoinitiators, wherein the liquid metal particles, monomers, crosslinkers, and photoinitiators are dissolved in a solvent; projecting a light to the ink, wherein the light has a pattern, wherein the ink is exposed to the light and the light initiates a photopolymerization process where the monomers are polymerized and crosslinked with the liquid metal particles to form a composite on the substrate; wherein the composite conforms to the pattern; and sintering the composite via mechanical activation such that the liquid metal particles coalesce to form a continuous conductive layer anchored by the polymerized and crosslinked monomers.

In some embodiments, the ink further comprises one or more dispersants configured to disperse the liquid metal particles and stabilize the ink.

In some embodiments, each of the liquid metal particles comprises an oxide shell and the oxide shell is modified with ligands.

In some embodiments, each of the liquid metal particles comprises Ga and at least one of In, Sn, Bi, Sb, and Zn.

In some embodiments, each of the liquid metal particles comprise EGaIn.

In some embodiments, the oxide shell comprises a metal oxide comprising at least one cation derived from a metal selected from the group consisting of Ga, In, Sn, Bi, Sb, and Zn.

In some embodiments, each of the ligands is covalently or coordinatively bound to the oxide shell; wherein a terminal end of each of the ligands comprises an alkene group or a thiol group to enable crosslinking.

In some embodiments, the ligands comprise at least one functional group selected from the group consisting of a hydroxyl, thiol, a phosphonic acid, a carboxylic acid, a silane, and an amine.

In some embodiments, each of the monomers comprises an acrylate for the photopolymerization process.

In some embodiments, the crosslinkers comprise at least one crosslinker selected from the group consisting of a diacrylate, a trifunctional acrylate, and a tetrafunctional acrylate.

In some embodiments, the dispersants comprise at least one material selected from the group consisting of a polymeric dispersant, an anionic surfactant, a cationic surfactant, and a zwitterionic dispersant.

In some embodiments, the photoinitiators comprise at least one material selected from the group consisting of a Type-I α-cleavage initiator, a Type-II initiator, a photoredox catalyst, an acylgermane, a cationic, and a hybrid system.

Some embodiments further comprise sintering the composite mechanically, chemically, or electrically.

In some embodiments, the substrate is rigid, flexible, or stretchable.

In some embodiments, the light is UV light.

In some embodiments, the continuous conductive layer of the composite is a continuous layer of liquid metal formed by coalescence of the liquid metal particles.

Some embodiments further comprise projecting the light using digital light processing or optical maskless lithography.

Some embodiments further comprise projecting the light from under the substrate; wherein the substrate is transparent to the light.

Some embodiments further comprise exposing the ink to the light for less than or equal to 30 seconds.

Some embodiments include an ink, comprising: liquid metal particles, monomers, crosslinkers, photoinitiators, and dispersants; wherein the liquid metal particles, monomers, crosslinkers, photoinitiators and dispersants are dissolved in a solvent to form the ink; wherein the ink is configured to be deposited on a substrate; and wherein, when exposed to a light, the ink is configured to undergo a photopolymerization process where the monomers are polymerized and crosslinked with the liquid metal particles to form a composite on the substrate; wherein, upon mechanical activation, the liquid metal particles are configured to coalesce to form a continuous conductive layer anchored by the polymerized and crosslinked monomers.

In some embodiments, the light has a pattern and the composite conforms to the pattern.

In some embodiments, each of the liquid metal particles comprises an oxide shell and the oxide shell is modified with ligands.

In some embodiments, each of the liquid metal particles comprises Ga and at least one of In, Sn, Bi, Sb, and Zn.

In some embodiments, each of the liquid metal particles comprises EGaIn.

In some embodiments, the oxide shell comprises a metal oxide comprising at least one cation derived from a metal selected from the group consisting of Ga, In, Sn, Bi, Sb, and Zn.

In some embodiments, each of the ligands is covalently or coordinatively bound to the oxide shell; wherein a terminal end of each of the ligands comprises an alkene group or a thiol group to enable crosslinking.

In some embodiments, each of the ligands comprises at least one functional group selected from the group consisting of a hydroxyl, a thiol, a phosphonic acid, a carboxylic acid, a silane, and an amine.

In some embodiments, each of the monomers comprises an acrylate for the photopolymerization process.

In some embodiments, the crosslinkers comprise at least one crosslinker selected from the group consisting of a diacrylate, a trifunctional acrylate, and a tetrafunctional acrylate.

In some embodiments, the dispersants comprise at least one material selected from the group consisting of a polymeric dispersant, an anionic surfactant, a cationic surfactant, and a zwitterionic dispersant.

In some embodiments, the photoinitiators comprise at least one material selected from the group consisting of a Type-I α-cleavage initiator, a Type-II initiator, a photoredox catalyst, an acylgermane, a cationic and hybrid system.

In some embodiments, the substrate is rigid or flexible.

In some embodiments, the light is UV light.

Some embodiments include a device, comprising: a patterned liquid metal layer; wherein the patterned liquid metal layer comprises liquid metal particles; a polymer layer; and a substrate; wherein the patterned liquid metal layer is anchored to the substrate via the polymer layer.

In some embodiments, the substrate is rigid, flexible, or stretchable.

In some embodiments, the patterned liquid metal layer is a continuous layer of liquid metal formed by coalescence of the liquid metal particles.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description will be more fully understood with reference to the following figures, which are presented as embodiments of the invention and should not be construed as a complete recitation of the scope of the invention, wherein:

FIG. 1 illustrates a method of liquid metal printing conductive patterns on a substrate in accordance with some embodiments.

FIGS. 2A through 2H illustrate parameters in the fabrication process in accordance with an embodiment.

FIG. 3 illustrates the initial conductivity and stretchability with various stretchable conductors.

FIGS. 4A through 4F illustrate electromechanical characteristics of printed LM patterns in accordance with an embodiment.

FIG. 5A though 5F illustrate printed LM-polymer patterns in accordance with some embodiments.

FIGS. 6A through 6G illustrate printed LM circuits for wearable electronics in accordance with some embodiments.

FIGS. 7A through 7F illustrate printed LM circuits for soft robotics in accordance with some embodiments.

FIGS. 8A and 8B depict schematics of the liquid metal printing apparatus in accordance with some embodiments.

FIG. 9 illustrates a method of preparing a modified LMP stock solution in accordance with some embodiments.

FIG. 10A though 10G illustrate the mechanisms of LM printing via DLP-based projection lithography in accordance with some embodiments.

FIG. 11 illustrates fabrication of conductive liquid metal patterns via projection lithography in accordance with an embodiment.

### DETAILED DESCRIPTION OF THE INVENTION

Methods and processes for implementing fast and facile digital light processing (DLP)-based liquid metal printing are presented in accordance with this disclosure. Many embodiments allow that with 5-10 seconds of patterned UV-light exposure, a highly conductive and stretchable pattern can be printed using a photo-crosslinkable liquid metal (LM) particle ink.

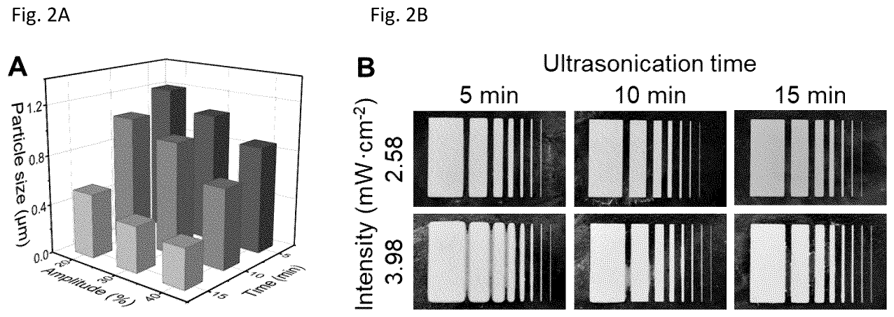

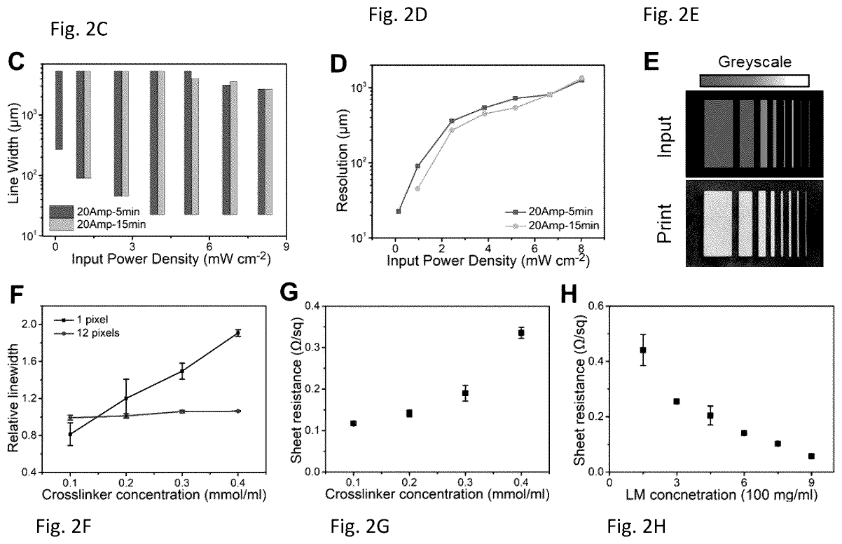

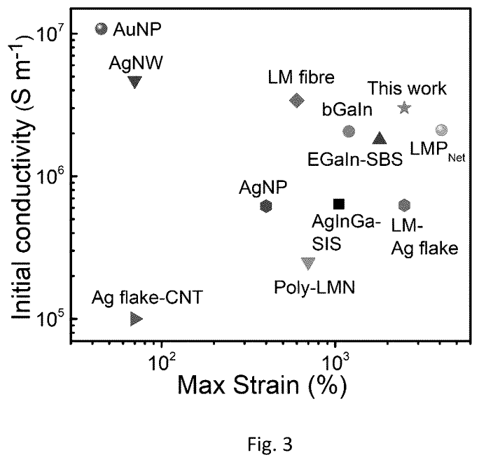

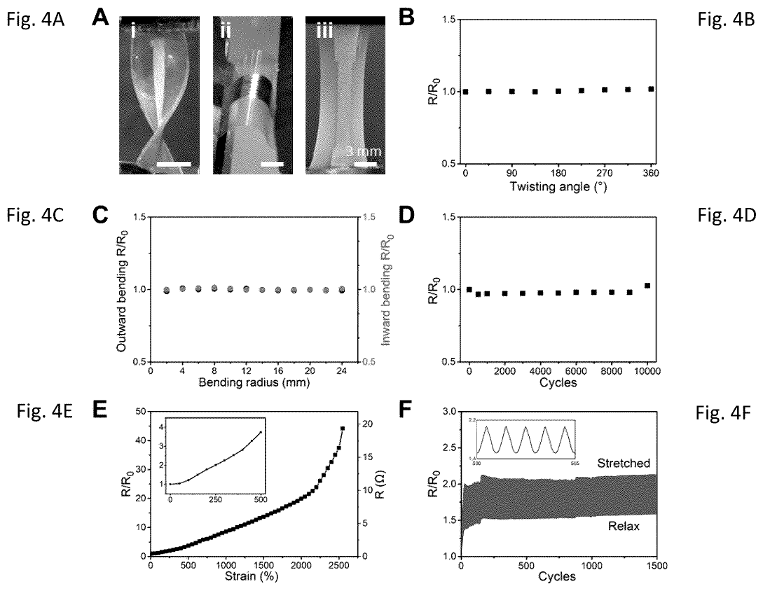

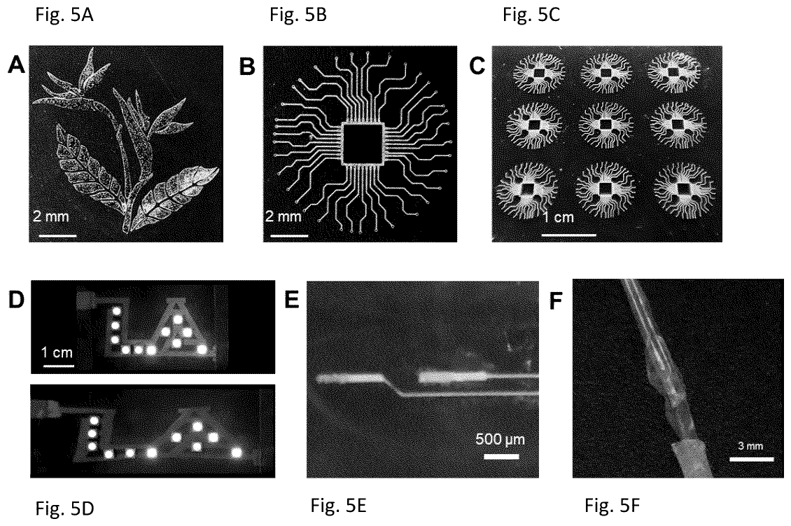

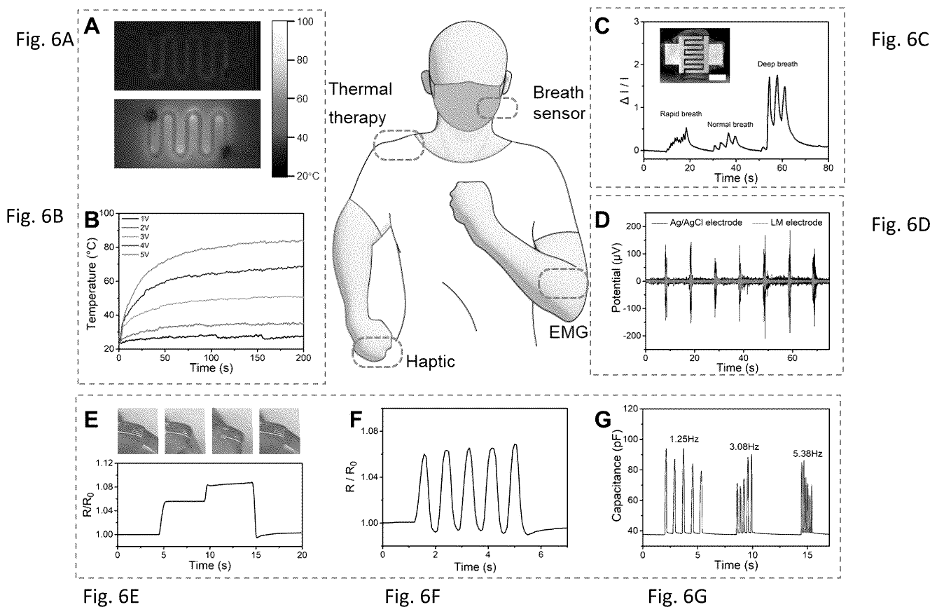

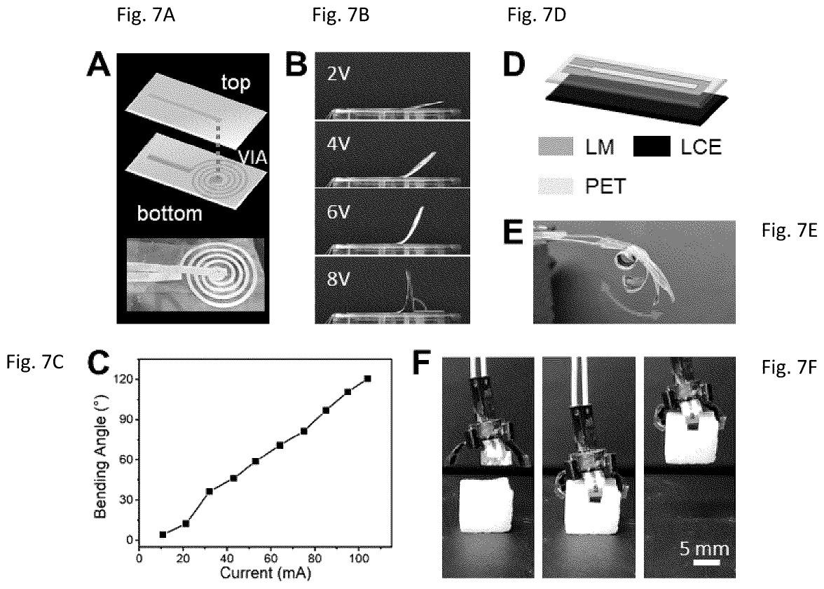

Various embodiments provide printed eutectic gallium indium traces featuring high resolution (greater than or equal to about 20 μm), as exemplary illustrated by FIG. 2D, conductivity (about 3.0×10⁶ S m⁻¹), stretchability (about 2500%) as exemplary depicted in FIG. 3, and stability (consistent performance at different deformation) as exemplary depicted in FIGS. 4A through 4F. Using processes and methods according to embodiments various patterns have been printed as exemplary shown by FIGS. 5A through 5F in diverse material systems for broad applications, including stretchable displays, epidermal strain sensors, heaters, humidity sensors, conformal electrodes for electrography as exemplary depicted in FIGS. 6A through 6G and multi-layer actuators as exemplary illustrated by FIGS. 7A through 7F.

Many embodiments of the disclosure are directed to the printing of LMs with DLP. These embodiments enable entire soft devices to be fabricated by one printer in a streamlined and efficient process. Printed liquid metal patterns, for example eutectic gallium indium (EGaIn), in accordance with various embodiments exhibit electrical conductivity at the same level as bulk EGaIn, and stretchability comparable or superior to the EGaIn-based conductors printed by direct writing, screen printing or transfer printing. Embodiments, of the present liquid metal printing technique is a fast, scalable, nozzle-free, photo-induced, parallel direct printing process, avoids the drawbacks of other liquid metal printing techniques mentioned above.

Various embodiments provide a fast, facile and scalable process, enabling patterning of conductive liquid metals by exposing a liquid metal particles (LMPs) ink to digitally generated light patterns for a few seconds; operating in ambient conditions at room temperature with low energy input and simple mechanical sintering, avoiding involving high-temperature environment and chemical, thermal or high-energy sintering processes, which might cause damage to polymeric substrates or other components; simultaneously generating LM-polymer structures in one step, in which highly conductive LM is confined and anchored to substrate via the polymer; capable of creating 2D conductive patterns and 3D structures on choices of arbitrary substrates such as various plastics and elastomer, especially benefiting the flexible and stretchable electrically conductive metal patterning for proof-of-concept, prototyping and rapid manufacturing; using simple setup based on a commercial spatial light modulator, a relatively lower-energy UV LED light source, without complex design and high-cost optical parts. Overall, these features make such fast and facile, room-temperature, one-step liquid metal patterning technique desired for fabricating flexible/stretchable electronics, bioelectronics and wearable electronics and soft robotics.

The liquid metal printing technique in accordance with various embodiments is based on a selectively photopolymerization of the LMP ink. The LMP ink may comprise LMPs, monomers and crosslinkers, to generate an LMP-polymer composite and then activated via mechanical sintering to form conductive LM-polymer patterns. The design and process in accordance with many embodiments can be divided into four main components, namely an illumination system, a LMP photocurable ink, substrates and mechanical sintering.

### Illumination System

Various embodiments of the illumination system comprise a light source, a spatial light modulator, optical parts including pertinent light convergent or divergent and collimating parts. The light source could be UV or white light dependent on the photoinitiator used in the ink. It could be monochromatic or polychromatic. The spatial light modulator providing patterned light for the design could be digital micromirror device (DMD), liquid crystal display (LCD) or scanning laser. The optical parts are utilized based on the choice of light source and the spatial light modulator for the purpose of light path alignment and focusing.

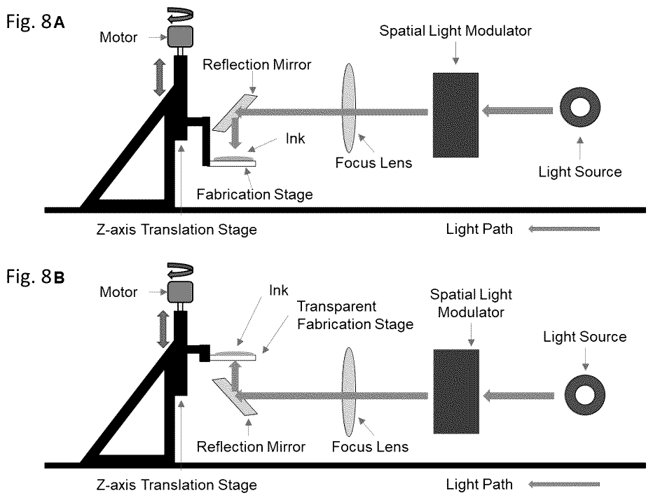

Liquid metal printing apparatuses are shown as exemplary illustrated by FIGS. 8A and 8B. Light from the light source can be modulated by a spatial light modulator. The light passes through focus lenses to focus on a reflection mirror. The reflected light focuses on a fabrication stage, where the ink is placed upon the fabrication stage. The reflected light off the reflection mirror can cure the polymer ink to initiate the photolithography process. The movement of the fabrication stage can be controlled via motors. The light path could be set either from above (top-down) as shown in FIG. 8A or below (bottom-up) as shown in FIG. 8B, the fabrication stage and substrate. For bottom-up configurations, the fabrication stage and substrates need to be transparent to the light.

### Liquid Metal Particle Photocurable Ink

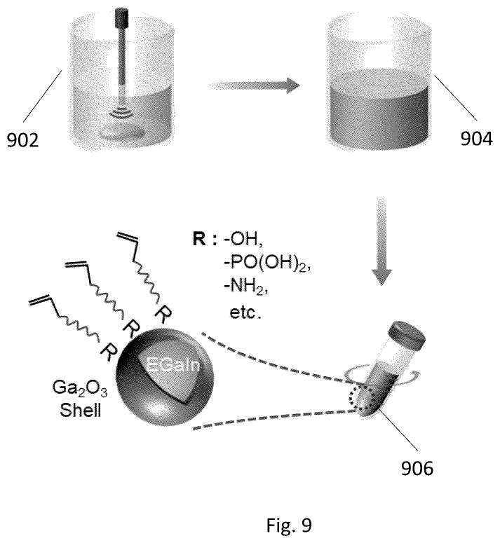

Many embodiments of the photo patternable LMP ink are composed of LMPs with modified surfaces, monomers, crosslinkers, dispersant, photoinitiator and solvent. The LMPs could be any liquid metals or alloys that are in stable liquid phase at room temperature (from about 15° C. to about 25° C.) and can be fabricated into stable micro/nano droplets/particles, the surfaces of which could be chemically modified. In some embodiments, EGaIn (Ga 75.5%, In 24.5%) can be used. As illustrated in FIG. 9 bulk EGaIn could be shattered into particles when subjected to fierce shearing forces as shown in 902, such as ultrasonication or vortex. In addition, a thin Ga₂O₃ layer (2-3 nm) will form spontaneously on the surface of either bulk EGaIn or EGaIn particles when exposed to oxygen or water as shown in 904. Such oxide layer can be chemically modified with diverse ligands via anchoring groups such as (but not limited to) hydroxyl, thiol, phosphonic acid, carboxylic acid, silane, and amine. The surface modification (shown in 906) could modify LMPs surface with alkene or thiol groups which can be involved in photopolymerization process. Monomer can be 2-hydroxyethyl acrylate, acrylic acid or any other monomers which can form stretchable polymeric layer or matrix to be crosslinked with the modified LMPs and provide strong adhesion to the substrates. Crosslinkers can be poly(ethylene glycol) diacrylate (PEGDA), trimethylolpropane ethoxylate triacrylate (ETPTA), trimethylolpropane triacrylate, pentaerythritol tetraacrylate or any other chemicals which can crosslink the polymer chains and modified LMPs. Dispersant could be polyethylene glycol (PEO) with diverse molecular weight or any other chemicals which can help the dispersion of LMPs in the ink. Photoinitiator can be either water-soluble or water-insoluble determined by the solvent used. The absorption spectrum of photoinitiator should correspond with the wavelength of the light source employed. Examples of photoinitiator include (but are not limited to) diphenyl(2,4,6-trimethylbenzoyl)phosphine oxide, lithium phenyl-2,4,6-trimethylbenzoylphosphinate, phenylbis(2,4,6-trimethylbenzoyl)phosphine oxide, 2-hydroxy-4′-(2-hydroxyethoxy)-2-methylpropiophenone. Solvent could be either water or organic solvent which can enable the formation of a stable dispersion of LMPs.

### Substrates

In accordance with some embodiments, a variety of substrates can be chosen depending on various applications. Both rigid, flexible and stretchable substrates can be successfully patterned with conductive liquid metal. For instance, polyethylene terephthalate (PET) is a transparent, flexible and thermoplastic polymer for packaging, fabrics, textile and electronic. It can serve as flexible substrate for liquid metal printing without additional processing. Polystyrene-block-polyisoprene-block-polystyrene (SIS) is a transparent, stretchable and thermoplastic elastomer. It can serve as stretchable substrate for liquid metal printing without additional pretreatment. For substrates with a lower affinity to the photopolymer generated from LMP ink, surface pretreatment could be conducted to facilitate the adhesion between substrate and printed structures.

### Mechanical Sintering

In various embodiments, mechanical sintering may be introduced to activate the printed LMP-polymer pattern to achieve conductivity. By applying appropriate shearing stress to the oxide layer, the oxide layer can be easily broken, and the liquid metal would flow out forming continuous paths throughout the printed pattern. The mechanical sintering process could be rubbing, compressing, peeling stretching or ultrasonicating determined by the structures and the mechanical properties of the LMP-polymer pattern.

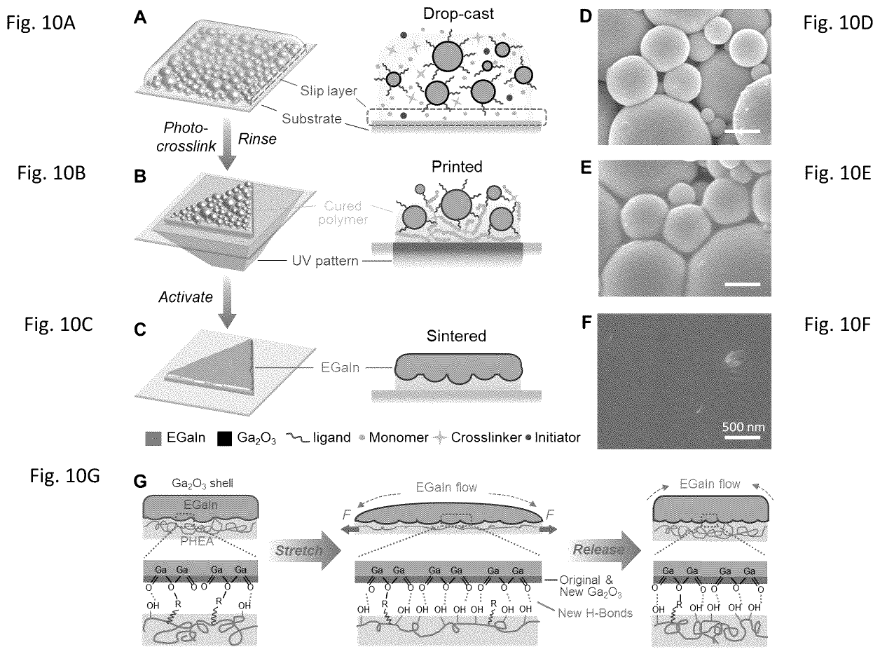

FIGS. 10A through 10G illustrate the mechanism of LM printing via DLP-based projection lithography. The process can start with drop-casting LM ink on a substrate as shown in FIG. 10A. A slip layer can be formed between the LM ink and the substrate. FIG. 10D shows an SEM image of the LM particle ink comprising EGaIn particles with Ga₂O₃ shells. The ink comprises ligands, monomers, crosslinkers, photoinitiators suitable for the photocrosslink processes. The monomers can be poly(hydroxyethyl acrylate) (PHEA). A patterned UV light can be applied to the ink to selectively cure the polymers as shown in FIG. 10B. Crosslink activates the monomers, crosslinkers, photoinitiators in the LM particle ink to form an LM particle-polymer composite. FIG. 10E shows an SEM image of the LM particle-polymer composite. The LM particle-polymer composite can be activated via sintering as shown in FIG. 10C. Sintering process forms conductive LM-polymer patterns. FIG. 10C shows an SEM image of the conductive LM-polymer layer. FIG. 10G shows a schematic of interfacial reconciliation between the EGaIn and the PHEA layer upon stretching and releasing. The PHEA layer can be formed on the Ga₂O₃ shells of the EGaIn via crosslinking. During stretching, hydrogen bonds can be formed between the hydroxyl groups of PHEA layer and the oxygen atoms in the Ga₂O₃ shells. During release, some of the hydrogen bonds break and the EGaIn and PHEA polymer layer returns to the original shape.

### Printing Process

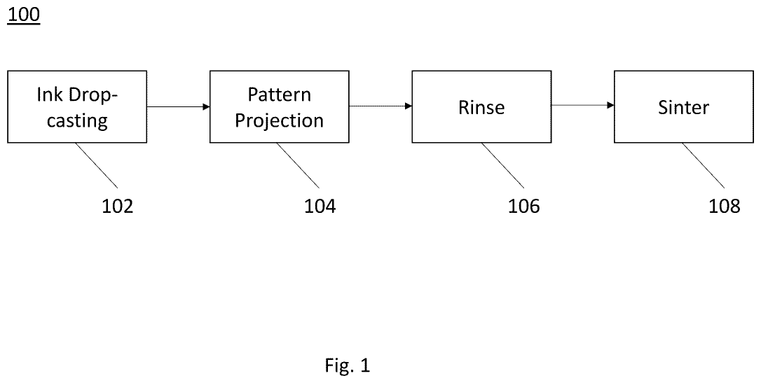

Various embodiments of the printing process 100 are illustrated in FIG. 1. The LM polymer ink may be drop-cast onto a substrate 102. The substrate can be transparent and/or flexible. The ink comprises LM particles, monomers, crosslinkers, and photoinitiators. An UV light with desired patterns may be projected onto the ink 104. The UV light can be applied from the bottom of the substrate at the interface between the ink and substrate using the illumination system until the ink cures. The UV light can be applied from the top of the substrate using the illumination system until the ink cures. After a few seconds of exposure, a non-conductive crosslinked LMP pattern can be printed on the substrate. The crosslinked LM polymer pattern comprises conductive LM particles and crosslinked polymers. The non-crosslinked components can be rinsed 106 away and a clear LMP-polymer pattern can be obtained. The LMP-polymer pattern may be activated with mechanical sintering 108 to form a highly conductive LM-polymer pattern.

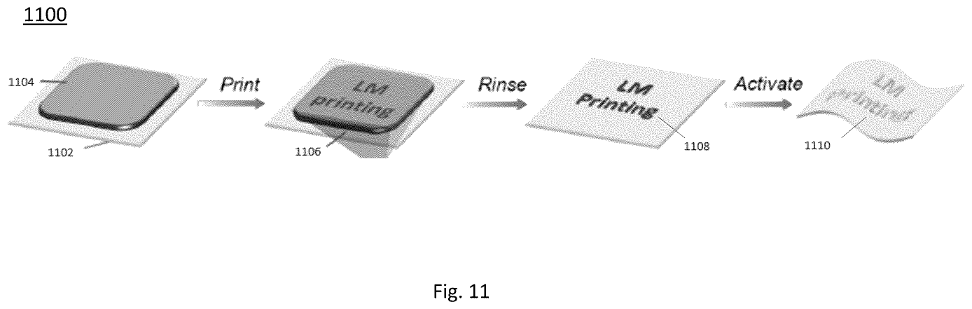

In various exemplary embodiments it has been demonstrated that EGaIn can be printed on flexible PET and stretchable SIS substrate with digital light processing (DLP) projector with the following procedure 1100, as illustrated in FIG. 11. The LMP ink can be prepared following the procedures in FIG. 9. Briefly, a modified liquid metal particle stock solution can be prepared. Bulk EGaIn is first mixed with modifying agents in ethanol, and the mixture is ultrasonicated shattering the bulk EGaIn into micro/nanoparticles. The mixture is then concentrated to form a modified LMP stock solution. Then the printable LMP ink is prepared by mixing the as-prepared modified LMP stock solution, PEO-200 solution as dispersant solution, and ETPTA-912 solution as crosslinker solution, with the adhesive monomer 2-HEA, at an appropriate volume ratio, for example, 15:5:5:1. Lastly, 0.4 vol % of TPO as photoinitiator can be added into the above mixture and mixed under vortex. The image projection system comprising a commercially available 385 nm UV DLP projector with projection lens and a beam splitter. Digital black and white patterns are generated using software. The designed patterns are then converted into UV light patterns via the projection system. The field of view and the resolution of the patterns can be manipulated by tuning or changing different projection lenses. A substrate 1102 is placed on the printing stage of the apparatus and the focus plane of the projection system is adjusted to the surface of the substrate. In various embodiments as shown in FIG. 11, the LMP ink 1104 is drop-cast onto the substrate and then the designed UV light pattern 1106 is projected for about 10 seconds. After that, ethanol is used to rinse away the nonreacted component and an LMP-polymer pattern can be observed printed on the substrate 1108. The printed LMP-PHEA pattern is mechanically sintered by gently rubbing the surface of the pattern to form a highly conductive LM-polymer traces 1110.

Some exemplary embodiments of EGaIn patterns printed on PET substrate are shown in FIGS. 5A through 5D using the processes described above. FIG. 5A shows a bird of paradise flower pattern printed using the LPM ink. FIG. 5B shows a printed circuit using the EGaIn LPM ink. In FIG. 5C, a 3×3 array of a circuit pattern can be printed within 10 seconds demonstrating the potential for rapid manufacturing of this liquid metal printing technique. FIG. 5D shows that LEDs can be mounted onto the printed stretchable EGaIn circuit and function correctly under stretching. In other exemplary embodiments as show in FIG. 5E a LM electrode can be printed on stretchable substates. In other such exemplary employments the LM electrode can be incorporated into other devices such as a catheter balloon as illustrated in FIG. 5F.

Printing resolution equal to or greater than about 20 μm can be achieved in accordance with such embodiments. Conductivity of the printed patterns can reach up to about 3.0×10⁶ S/m. The parameters of the pattern formation, including ink formulation and light exposure, have been shown in FIGS. 2A through 2H. The LMP size and distribution, the exposure intensity, the concentration of crosslinker and LM loading are closely related to the resolution, the linewidth, the patterning accuracy and sheet resistance of the printed patterns. The properties of the printed LM patterns (resolution, linewidth, sheet resistance) are optimized by tuning the LMP fabrication conditions to change the particle size and its distribution; adjusting printing parameters including the intensity of light, irradiation time, irradiation approach (pulse/continuous), wavelength, etc.; changing the chemistry of the LMP ink, including modifying agent of LMP, the component chemicals, as well as their concentrations and ratios in the ink. In addition, the printed LM-polymer structures can also be changed by tuning the LMP ink and printing conditions. The structures could be either laminated multi-layered or bicontinuous networks.

FIG. 2A shows average LMP sizes under different ultrasonication amplitude and time. FIG. 2B shows strip patterns printed with different light intensities. FIG. 2C shows linewidth range of the printed strips with varied input power densities. FIG. 2D shows resolution of the printed traces with varied input power densities. FIG. 2E shows a greyscale digital image (top) and corresponding printed LMPs pattern (bottom). FIG. 2F shows relative linewidths of printed strips using inks with varied crosslinker concentrations. FIG. 2G shows sheet resistance of printed pattern as a function of crosslinker concentration in LMP inks. FIG. 2H shows sheet resistance of printed pattern as a function of LM concentration in LMP inks.

The exemplary printed EGaIn patterns exhibit electromechanical stability when subjected to different deformation modes as shown in FIGS. 4A through 4F. The printed traces show negligible resistance change when undergoing twisting and bending. Low resistance change at low strain and notably high stretchability was observed when the printed traces were stretched. The resistance changes measured at low strain (R/R0≈1.22 at 100% strain and R/R0≈3.74 at 500% strain) are much smaller than the theoretical prediction for an incompressible, constant-conductivity bulk liquid metal conductor using Pouillet's law (R/R0=(1+ε)2, where ε is the applied strain; R/R0=4 at strain of 100%, R/R0=36 at strain of 500%). The printed trace can remain conductive at a high strain (2500%). Additionally the printed EGaIn can keep a consistent electromechanical performance over 1500 stretching-relaxing cycles at a strain of 100%.

FIG. 4A shows printed LM traces subjected to (i) twisting, (ii) bending and (iii) stretching. FIG. 4B shows relative resistance changes as a function of twisting angle. FIG. 4C shows relative variation in resistance under outward and inward bending. FIG. 4D shows relative resistance change of printed LM trace subjected to cyclic bending. FIG. 4E shows relative resistance/resistance (Ω) variation as a function of strain. FIG. 4F shows relative variation in resistance during cyclic stretching.

In some embodiments of EGaIn-PHEA printing as depicted in FIG. 10A though 10G, upon irradiation of 10 seconds under a 385 nm UV light pattern with an intensity as low as ˜3 mW/cm⁻², EGaIn patterns with a high resolution (˜20 μm), a high conductivity (3.0×10⁶ S m−1), high stretchability (˜2500%) and stability (consistent performance at different deformation) as depicted in FIG. 4A though 4F. The electrical and electromechanical performances of the printed LM-polymer are further improved by optimizing the LMP ink composition, illumination systems, printing parameters, and substrate selection.

The fast and facile photo-induced liquid metal printing technique in accordance with embodiments exhibits the capability of fabricating flexible and stretchable LM-polymer patterns with high resolution, high electrical conductivity, high stretchability and electromechanical stability, in mild manufacturing conditions, such as room temperature in ambient conditions, using commercially available optical maskless lithography with low energy input and short processing time. The design is facile, scalable, highly efficient, inexpensive and possesses high value for diverse applications in flexible electronics, wearable electronics, bioelectronics and soft robotics as illustrated in FIG. 6A though 6G and FIG. 7A though 7F. Many embodiments enable the printing of flexible and stretchable EGaIn patterns on various substrates in room-temperature ambient conditions using UV light DLP projection lithography.

The present liquid metal printing technique extends the choice of printable metallic materials with optical maskless lithography and enables the printed liquid metal patterns in broad applications. Liquid metal printing in accordance with many embodiments can be applied to various flexible and stretchable substrates and integrated with different functional materials to meet requirements of diverse applications, such as flexible devices, wearable electronics and bioelectronics. Flexible electronics can be achieved by printing liquid metal patterns on flexible or stretchable substrates and mounting electronic components, such as switch, resistors, capacitors, light-emitting diodes and microchips, onto the patterns. The printed liquid metal patterns serve as circuits for flexible displays, foldable screens, electronics tags or as electrical wires to connect different electronic modules. Wearable electronics can be achieved by printing liquid metal patterns on flexible or stretchable substrates and applying diverse functional materials or electronic components to the patterns. Liquid metal patterns can also serve as various functional circuits. Resistive strain sensors with wave-shaped patterns can serve for gesture monitoring, and capacitive pressure sensors with interdigitated patterns can serve for touch and pressure detection. Soft liquid metal circuits based wearable electronics, including smart watches, smart rings, smart hand straps, electronic skins and smart textiles, etc., can provide enhanced human-machine interaction experience. Bioelectronics can be achieved by printing liquid metal patterns on conformal substrates and integrating them with bioelectronic components. Printed liquid metal could serve as either circuits or electrodes. Due to the facile printing process, the ease of applying biomaterials to the printed liquid metal patterns, and the excellent conformability of the conductive patterns, the present printing technique could be utilized for fabricating bioelectronic devices for health monitoring, disease diagnosis and therapeutic treatment.

In many embodiments the liquid metal printing technique utilizes light and LMP ink to generate conductive liquid metal patterns, which are maskless and nozzle-free. The patterns form in parallel within a single light exposure and significantly reduces the fabrication time of pattern to seconds. In addition, liquid metals are intrinsically stretchable at room temperature, largely enhances the electromechanical performance of flexible/stretchable electronics.

FIG. 6A though 6G illustrates embodiments of applications of the technique in fabricating flexible and stretchable wearable devices. EGaIn can be printed into a wave-shaped pattern serving as a resistive LM heater for thermal therapy. FIG. 6A shows IR thermal images of the LM heater. FIG. 6B shows temperature evolution of the flexible LM heater. EGaIn can be printed into an interdigitated pattern and integrated with polyvinyl alcohol (PVA) film to fabricate a humidity sensor for breath monitoring and show in FIG. 6C. FIG. 6C also shows leakage current curve of the proposed breath sensor. Conformal EGaIn electrode can be printed electromyography (EMG) signal monitoring as shown in FIG. 6D. FIG. 6D also shows EMG signals collected by LM electrodes. Printed EGaIn patterns can also be used as sensors in haptic applications, such as hand gesture monitoring and finger contact detection as shown in FIG. 6E. FIG. 6E also shows resistance variation of the LM strain sensor on a finger. FIG. 6F shows resistance variation of the LM strain sensor under multiple finger-bending cycles. FIG. 6G shows capacitance curve of the proposed sensor for finger contact.

Liquid metal printing techniques in accordance with embodiments can be not only applied to flexible and stretchable electronics, but also to soft robotics. The printed liquid metal patterns could serve as both electrical and thermal conductors and be integrated with soft smart materials for soft robotics due to their excellent conformability. Electromagnetically driven soft robotics can be achieved by printing liquid metal patterns with coil shape on flexible thin film substrates. Placing the printed circuit in a magnetic field and applying an input current through the liquid metal patterns, an instant magnetic field can be generated. Due to the softness of the substrate, the magnetic force applied on the circuit can be easily manipulated by changing the current and its direction, thus realizing the electrical control of the soft robotic movement. Electrothermally driven soft robotics can also be achieved by integrating printed liquid metal patterns with thermally actuated materials, such as shape memory polymer and liquid crystal elastomer, or heterogeneous structures composed of materials of different thermal expansion coefficients. Liquid metal patterns can be printed on soft substrate and laminated with thermal actuator or directly printed on the actuator. As the current flows through the printed liquid metal patterns, heat could be generated and transfer instantly to the thermal actuator, leading to the deformation of the smart materials, achieving electrical control of the soft robotics.

The liquid metal printing technique in some embodiments enables fabrication of highly conductive and highly conformable liquid metal circuits with electromechanical stability on flexible and stretchable thin-film substrates. The digital pattern creating process and optical lithography ensure great flexibility in pattern design. 2D and 3D circuits can be designed, printed and integrated into soft robots to achieve electrical control of the soft robot's movement and interactions to its environment.

FIG. 7A though 7F illustrate applications of printed LM circuits for soft robotics in accordance with several embodiments. In FIG. 7A, a spiral and a rectangular EGaIn patterns are printed separately and then laminated and connected with a vertical interconnect access to for a flexible thin-film electromagnetic actuator, which can bend at different angles in accordance to the applied voltages in a magnetic field. FIG. 7B shows images of the actuator bending with varied input voltages. FIG. 7C shows bending angle variation as a function of applied current. Printed EGaIn can be combined with liquid crystal elastomer (LCE), which is a thermal-responsive smart material, to fabricate an electro-driven flexible thin-film actuator. FIG. 7D illustrates a schematic of the bilayer LM-LCE actuator. FIG. 7E shows images of the bilayer LM-LCE actuator rolling up with an input current of 100 mA. FIG. 7F shows LM-LCE gripper picking up a soft sponge cube via electrothermal actuation.

### DOCTRINE OF EQUIVALENTS

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A system for liquid metal printing, comprising:
a substrate configured to hold an ink, wherein the ink comprises liquid metal particles, monomers, crosslinkers, photoinitiators, and a solvent, wherein the liquid metal particles are dispersed in the solvent, and the monomers, crosslinkers, and photoinitiators are dissolved in the solvent; wherein each of the liquid metal particles comprises an oxide shell and the oxide shell is modified with ligands;
a light source configured to emit a light;
a spatial light modulator configured to project the light with a pattern, wherein the light is projected to the ink on the substrate such that the ink is exposed to the light and the light initiates a photopolymerization process where the monomers are polymerized and crosslinked with the liquid metal particles to form a composite on the substrate; wherein the composite conforms to the pattern; and
a sintering apparatus, wherein the sintering apparatus is configured to apply a mechanical activation to the composite; wherein the mechanical activation ruptures the oxide shell and coalesces the liquid metal particles to form a continuous conductive layer atop the polymerized and crosslinked monomers.

2. The system for liquid metal printing of claim 1, wherein the ink further comprises one or more dispersants configured to disperse the liquid metal particles and stabilize the ink.

3. The system for liquid metal printing of claim 1, wherein each of the liquid metal particles comprises a gallium-based alloy in a liquid form at a temperature range between 15 degrees Celsius and 25 degrees Celsius; wherein each of the liquid metal particles further comprises at least one of In, Sn, Bi, Sb, and Zn.

4. The system for liquid metal printing of claim 1, wherein each of the liquid metal particles comprises EGaIn.

5. The system for liquid metal printing of claim 1, wherein the oxide shell comprises a metal oxide comprising at least one cation derived from a metal selected from the group consisting of Ga, In, Sn, Bi, Sb, and Zn.

6. The system for liquid metal printing of claim 1, wherein each of the ligands is covalently or coordinatively bound to the oxide shell; wherein a terminal end of each of the ligands comprises an alkene group or a thiol group to enable crosslinking.

7. The system for liquid metal printing of claim 1, wherein each of the ligands comprises at least one functional group selected from the group consisting of a hydroxyl, a thiol, a phosphonic acid, a carboxylic acid, a silane, and an amine.

8. The system for liquid metal printing of claim 1, wherein each of the monomers comprises an acrylate for the photopolymerization process.

9. The system for liquid metal printing of claim 1, wherein the crosslinkers comprise at least one crosslinker selected from the group consisting of a diacrylate, a trifunctional acrylate, and a tetrafunctional acrylate.

10. The system for liquid metal printing of claim 2, wherein the one or more dispersants comprise at least one material selected from the group consisting of a polymeric dispersant, an anionic surfactant, a cationic surfactant, and a zwitterionic dispersant.

11. The system for liquid metal printing of claim 1, wherein the photoinitiators comprise at least one material selected from the group consisting of a Type-I α-cleavage initiator, a Type-II initiator, a photoredox catalyst, an acylgermane, a cationic, and a cationic hybrid system.

12. The system for liquid metal printing of claim 1, wherein the substrate is rigid or flexible.

13. The system for liquid metal printing of claim 1, wherein the light is UV light.

14. The system for liquid metal printing of claim 1, wherein the light is projected using digital light processing or optical maskless lithography.

15. The system for liquid metal printing of claim 1, wherein the light is projected from under the substrate; wherein the substrate is transparent to the light.

16. The system for liquid metal printing of claim 1, wherein the ink is exposed to the light less than or equal to 30 seconds.

17. A method, comprising:
depositing an ink on a substrate, wherein the ink comprises liquid metal particles, monomers, crosslinkers, photoinitiators, wherein the liquid metal particles, monomers, crosslinkers, and photoinitiators are dissolved in a solvent;
projecting a light to the ink, wherein the light has a pattern, wherein the ink is exposed to the light and the light initiates a photopolymerization process where the monomers are polymerized and crosslinked with the liquid metal particles to form a composite on the substrate; wherein the composite conforms to the pattern; and
sintering the composite via mechanical activation such that the liquid metal particles coalesce to form a continuous conductive layer anchored by the polymerized and crosslinked monomers.

18. The method of claim 17, further comprising projecting the light using digital light processing or optical maskless lithography.

19. The method of claim 17, further comprising projecting the light from under the substrate for less than or equal to 30 seconds; wherein the substrate is transparent to the light.

20. An ink, comprising: liquid metal particles, monomers, crosslinkers, photoinitiators, and dispersants; wherein the liquid metal particles, monomers, crosslinkers, photoinitiators and dispersants are dissolved in a solvent to form the ink;
wherein the ink is configured to be deposited on a substrate; and
wherein, when exposed to a light, the ink is configured to undergo a photopolymerization process where the monomers are polymerized and crosslinked with the liquid metal particles to form a composite on the substrate; wherein, upon mechanical activation, the liquid metal particles are configured to coalesce to form a continuous conductive layer anchored by the polymerized and crosslinked monomers.
